(19) United States
(12) Patent Application Publication
(10) Pub. No.: US 2005/0164505 A1
(43) Pub. Date: Jul. 28, 2005

(54) Land grid array membrane

(76) Inventors: Tim A. Renfro, Mesa, AZ (US); Jiteender P. Manik, Chandler, AZ (US); Michael Li, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/765,653

(22) Filed: Jan. 26, 2004

(51) Int. Cl. H01L 21/302; H01L 21/461

(52) U.S. Cl. 438/689

(57) ABSTRACT

Embodiments of the invention provide a membrane for a land grid array (LGA) that reduces the likelihood and extent of deformation of the LGA contacts, as well as contamination thereof by foreign material. For one embodiment, the LGA has a number of holes formed therein that correspond to the LGA contacts and allow electrical coupling of the LGA contacts and pads of an IC device. For an alternative embodiment, the membrane has a number of conductive pads that correspond to the LGA contacts. These pads interface, in place of the LGA contacts, with the IC device pads, providing electrical connection between the IC device pads and the LGA contacts.

### FIELD

Embodiments of the invention relate, generally, to the field of integrated circuit devices and, more specifically, to integrated circuit packaging and land grid arrays.

### BACKGROUND

There are a multitude of electrical connections between the integrated circuits of an electronic device, such as a computer processor and other integrated circuits within the processor and eventually to other devices. With the ever-increasing complexity of components, such as microprocessors and application specific integrated circuits (ASICs), comes greater challenges in forming good electrical connections between the component and a printed circuit board. Some of the options include various small outline packages, plastic leaded chip carrier, dual inline packages, pin grid arrays, ball grid arrays, etc. Land grid array (LGA) sites are a popular way to connect such components to a printed circuit board.

LGA packages are ideal for devices, such as microprocessors, because the LGA package uses an array of contact pads on the component that are merged with similar contact pads on the printed circuit board, thus providing the required electrical connections between the integrated circuit device and the circuit board. The pitch of such electrical contacts can be very small. Typical LGA sockets include a base for seating the LGA package, which has a recessed portion in the middle of the socket base corresponding to the footprint of the LGA package to be inserted in the socket. This recessed portion operates to align the integrated circuit module to the electrical contacts within the socket, but also prevents the integrated circuit module from extending beyond the socket boundary. LGA sockets also typically include the same number of contacts providing electrical connections from the package to the circuit board, as the number of pads on the LGA package. An interposer between the chip package and the printed circuit board provides a frame that supports the chip package and also provides a conductive path for each of the contact pads.

The advantages of LGA socket connectors include: the capability to upgrade electronics in the field; flexibility in starting up and diagnosing an electronic system; reduction of cost required to rework the previously assembled board; reduction of mismatch between the coefficients of thermal expansion between the module and the board; improvement of electrical performance; and the compactness and low profile of the electrical connector designs. The main reason for terminating a device as an LGA may be to achieve higher pin counts with smaller packages. In short, the LGA offers a viable interconnection for high speed, high density integrated circuits.

Typical LGAs are not without disadvantages. In order to form a good electrical contact with such land grid array assemblies, the interposer's conductors need to be compressed. Thus, a normal force is applied to compress together the chip package and printed circuit board with the interposer sandwiched between. This force must be uniform, otherwise some of the contact pads will compress more than others, which may lead to a poor overall electrical contact. More problematic is that the force must be perpendicular to the point of tangency of the LGA contact or risk deforming the contact. That is, since the LGA contact is a very thin, hook-shaped conductor, if the compressive force is not direct the contact may get bent.

The LGA contacts can be deformed due to improper insertion or other handling, and may, as well, be contaminated by foreign material. That is, with the hooked shape of the contacts, it is easy for contaminating material, such as, for example, clothing threads, dust, or even conductive particles, to get lodged in or beneath the LGA contacts. Such contamination can impair the LGA performance or cause failure.

Over the lifetime of the LGA, the likelihood of a failure-causing deformation or contamination is high. Moreover, as the number of contacts on an LGA increases, the contacts will be thinner, and hence, more susceptible to deforming pressure.

### BRIEF DESCRIPTION OF THE DRAWINGS

The invention may be best understood by referring to the following description and accompanying drawings that are used to illustrate embodiments of the invention. In the drawings:

FIG. 1 illustrates a process for reducing the deformation and contamination of LGA contacts in accordance with one embodiment of the invention;

FIG. 2 illustrates an LGA with an LGA membrane attached in accordance with one embodiment of the invention;

FIG. 3 illustrates a side view of the application of a membrane to an LGA socket in accordance with one embodiment of the invention;

FIG. 4 illustrates a cross-sectional view of a pad incorporated within a membrane in accordance with one embodiment of the invention; and

FIG. 5 illustrates a membrane having conductive pads incorporated therein in accordance with one embodiment of the invention.

### DETAILED DESCRIPTION

In the following description, numerous specific details are set forth. However, it is understood that embodiments of the invention may be practiced without these specific details. In other instances, well-known circuits, structures and techniques have not been shown in detail in order not to obscure the understanding of this description.

Reference throughout the specification to “one embodiment” or “an embodiment” means that a particular feature, structure, or characteristic described in connection with the embodiment is included in at least one embodiment of the present invention. Thus, the appearance of the phrases “in one embodiment” or “in an embodiment” in various places throughout the specification are not necessarily all referring to the same embodiment. Furthermore, the particular features, structures, or characteristics may be combined in any suitable manner in one or more embodiments.

Moreover, inventive aspects lie in less than all features of a single disclosed embodiment. Thus, the claims following the Detailed Description are hereby expressly incorporated into this Detailed Description, with each claim standing on its own as a separate embodiment of this invention.

In accordance with one embodiment of the invention, a membrane is placed over the LGA contacts, thus reducing deformation due to indirect pressure (i.e., pressure in an unintended direction) and contamination due to foreign material coming in contact with the LGA contacts. For one embodiment, the membrane is placed over the LGA contacts through use of a frame.

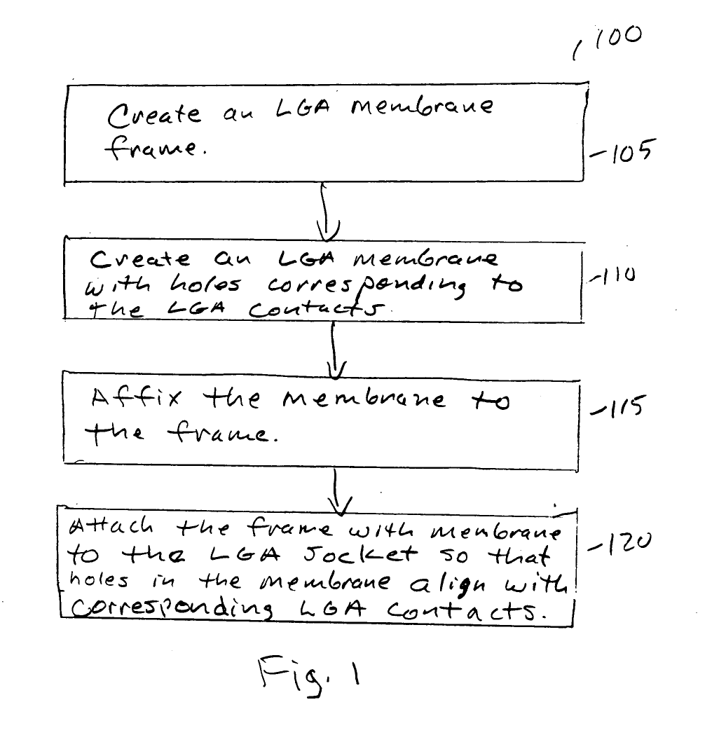

FIG. 1 illustrates a process for reducing the deformation and contamination of LGA contacts in accordance with one embodiment of the invention. Process 100, shown in FIG. 1, begins at operation 105, in which a LGA membrane frame is created. The frame is sized to fit the LGA socket and may be made with molded plastic. For one embodiment, the frame can be made to snap on to the LGA socket. In alternative embodiments, the frame may be made to attach to the LGA socket in any suitable manner.

At operation 110, an LGA membrane is created. The LGA membrane may be made from a flexible, durable, and non-conductive material for one embodiment. For one embodiment, the LGA membrane is made of a synthetic polymeric resin that is resistant to high temperature, wear, and corrosion (e.g., a polyimide film). The LGA membrane may be created with small holes that correspond to the LGA contacts so that electrical connection is possible between the contacts and the pads of an IC device. For one embodiment, the dimension of each hole corresponds to the portion of the corresponding LGA contact that interfaces with the IC device pads.

At operation 115, the LGA membrane is affixed to the frame. For one embodiment, a membrane material is sized and cut to fit the frame and is then stretched tightly across the frame.

At operation 120, the LGA frame is attached to the LGA socket such that holes in the membrane align to corresponding LGA contacts.

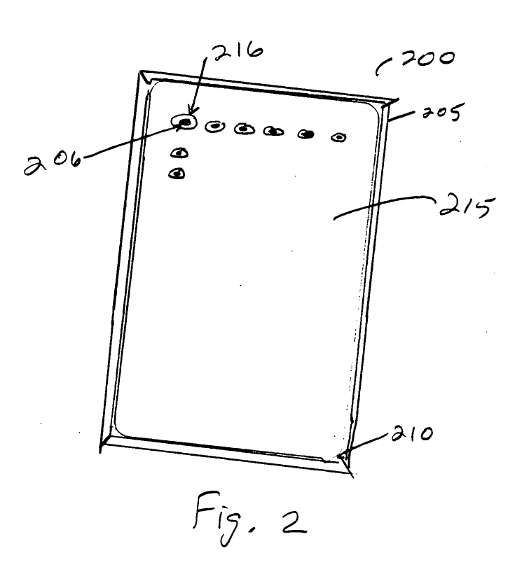

FIG. 2 illustrates an LGA with an LGA membrane attached in accordance with one embodiment of the invention. The membraned LGA device 200 includes an LGA socket 205 having a number of contacts 206 thereon. The contacts 206 are aligned with holes 216 in an LGA membrane 215. For one embodiment, the dimension of holes 216 are such that only that portion of each contact 206 that interfaces an IC device pads is exposed through a hole 216. The LGA membrane 215, which may be made of a polyimide film, is stretched across frame 210 to effect the alignment of holes 216 and contacts 206. Frame 210, which may be molded plastic, is attached to the LGA socket 205. For one embodiment, frame 210 is made to snap onto LGA socket 205.

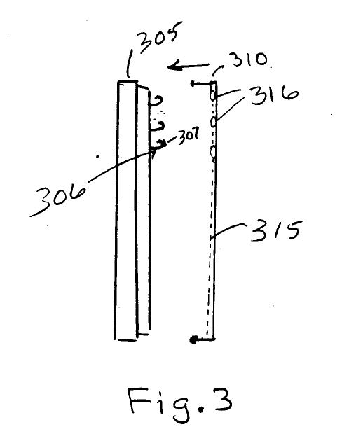

FIG. 3 illustrates a side view of the application of a membrane to an LGA socket in accordance with one embodiment of the invention. As shown in FIG. 3, frame 310 has membrane 315 affixed thereto. The membrane 315 has a number of holes formed therein that correspond to contacts 306 of LGA socket 305. In accordance with one embodiment of the invention, only the portion 307 of each contact 306 that interfaces an IC device pad is exposed through a hole 316.

The membrane, in accordance with various embodiments of the invention, reduces indirect pressure on the LGA contacts and reduces contamination of the contacts and the surrounding area. However, indirect pressure and contamination may be reduced further by providing a completely sealed LGA. In accordance with one embodiment of the invention, the membrane does not have holes through which corresponding LGA contacts interface the IC device pads. Instead, the membrane has pads incorporated therein that electrically interface corresponding LGA contacts and IC device pads.

For one embodiment of the invention, a membrane having incorporated pads is created using flexible circuit technology. A flexible interconnect (e.g., a pad) can be created by laminating a flexible polymer film to a thin sheet of conductive metal.

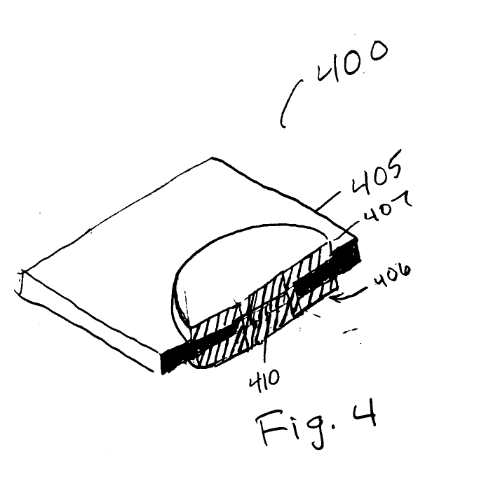

FIG. 4 illustrates a cross-sectional view of a pad incorporated within a membrane in accordance with one embodiment of the invention. Membrane portion 400, shown in FIG. 4, includes a membrane material 405 which may be a polyimide film. For one embodiment, Kapton®, available from Dupont Corporation of Wilmington, Del., is used due to its dimensional stability, dielectric strength, and flexural capability. Conductive metal pads 406 and 407 are connected through a via in the membrane by a conductive metal 410.

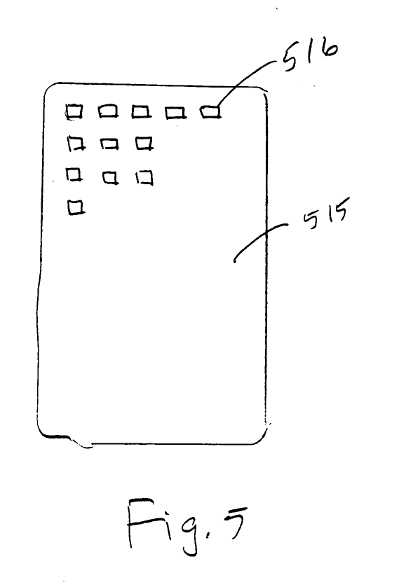

FIG. 5 illustrates a membrane having conductive pads incorporated therein in accordance with one embodiment of the invention. As shown in FIG. 5, membrane 515 has a number of pads 516 incorporated therein. Pads 516 are positioned so as to align with corresponding LGA contacts of an LGA device, not shown. For one embodiment, the membrane may be a flexible polymer and the pads 516 may be fabricated therein using conventional flexible circuit technology.

General Matters

Embodiments of the invention provide an LGA membrane that reduces the likelihood and extent of deformation of the LGA contacts, as well as contamination thereof by foreign material. For one embodiment, the membrane has a number of conductive pads that correspond to the LGA contacts. These pads interface, in place of the LGA contacts, with the IC device pads, providing electrical connection between the IC device pads and the LGA contacts.

Though described in reference to an LGA socket, embodiments of the invention are applicable to various types of direct socket loading (DSL) devices. For some DSL devices, an embodiment of the invention may be more applicable in reducing contamination of the contacts, while for other DSL devices, an embodiment of the invention may be more applicable to reducing the deformation of the contacts.

For various embodiments of the invention, the LGA membrane may be formed from a polyimide film, such as, for example, Kapton®, available from Dupont Corporation of Wilmington, Del. For alternative embodiments, the membrane may be any suitable, flexible material.

Embodiments of the invention include various operations. Many of the methods are described in their most basic form, but operations can be added to or deleted from any of the methods without departing from the basic scope of the invention.

While the invention has been described in terms of several embodiments, those skilled in the art will recognize that the invention is not limited to the embodiments described, but can be practiced with modification and alteration within the spirit and scope of the appended claims. The description is thus to be regarded as illustrative instead of limiting.

1. A method comprising:
forming a membrane for a direct socket loading device; and
attaching the membrane to the direct socket loading device.

2. The method of claim 1 wherein the direct socket loading device is a land grid array device.

3. The method of claim 2 wherein the membrane comprises a flexible, non-conductive material.

4. The method of claim 3 wherein one or more areas of the membrane allow electrical contact between the land grid array and an external device.

5. The method of claim 4 wherein the one or more areas of the membrane that allow electrical contact between the land grid array and an external device are holes formed within the membrane.

6. The method of claim 4 wherein the one or more areas of the membrane that allow electrical contact between the land grid array and an external device are pads incorporated within the membrane.

7. The method of claim 6 wherein the membrane comprises polyimide and the pads incorporated within the membrane are formed by flexible circuit technology.

8. The method of claim 5 wherein each of the holes is formed in the membrane in a location corresponding to a contact of the land grid array.

9. The method of claim 2 wherein the membrane is attached to a frame, the frame formed to connect to a socket of the land grid array.

10. A membrane comprising:
a flexible film material having formed therein one or more contact areas, each contact area corresponding to a contact of a direct socket loading device.

11. The membrane of claim 10 wherein the direct socket loading device is a land grid array device.

12. The membrane of claim 10 wherein the flexible film material comprises polyimide.

13. The membrane of claim 10 wherein the one or more contact areas are holes formed in the flexible film material.

14. The membrane of claim 10 wherein the one or more contact areas are conductive metal pads incorporated within the flexible film material.

15. A land grid array comprising:
a socket;
a plurality of contacts formed on the socket; and
a membrane covering the plurality of contacts, the membrane having formed therein one or more areas that allow electrical contact between the contacts and an external device.

16. The land grid array of claim 15 wherein the one or more areas of the membrane that allow electrical contact between the contacts and an external device are holes formed within the membrane.

17. The land grid array of claim 15 wherein the one or more areas of the membrane that allow electrical contact between the contacts and an external device are pads incorporated within the membrane.

18. The land grid array of claim 17 wherein the membrane comprises polyimide and the pads incorporated within the membrane are formed by flexible circuit technology.

19. The land grid array of claim 16 wherein each of the holes is formed in the membrane in a location corresponding to a contact of the land grid array.

20. The land grid array of claim 15 wherein the membrane is attached to a frame, the frame formed to connect to the socket.

21. A system comprising:
a processor; and
a direct socket loading device coupled to the processor, the direct socket loading device having a membrane attached thereto.

22. The system of claim 21 wherein the direct socket loading device is a land grid array device.

23. The system of claim 22 wherein the membrane comprises a flexible, non-conductive material.

24. The system of claim 23 wherein one or more areas of the membrane allow electrical contact between the land grid array and an external device.

25. The system of claim 24 wherein the one or more areas of the membrane that allow electrical contact between the land grid array and an external device are holes formed within the membrane.

26. The system of claim 24 wherein the one or more areas of the membrane that allow electrical contact between the land grid array and an external device are pads incorporated within the membrane.

27. The system of claim 26 wherein the membrane comprises polyimide and the pads incorporated within the membrane are formed by flexible circuit technology.

28. The system of claim 25 wherein each of the holes is formed in the membrane in a location corresponding to a contact of the land grid array.

29. The system of claim 22 wherein the membrane is attached to a frame, the frame formed to connect to a socket of the land grid array.
